(19) United States
(12) Patent Application Publication
(10) Pub. No.: US 2025/0259885 A1
(43) Pub. Date: Aug. 14, 2025

(54) METHOD OF MANUFACTURING SEMICONDUCTOR DEVICE

(71) Applicant: SAMSUNG ELECTRONICS CO., LTD., Suwon-si (KR)

(72) Inventors: Hanbyul Kang, Suwon-si (KR); Jaeho Kim, Suwon-si (KR); Minwoo Park, Suwon-si (KR); Jong Hwan Park, Suwon-si (KR); SANGHOON AHN, Suwon-si (KR); SeongJune Jeong, Suwon-si (KR); Donghyun Ko, Suwon-si (KR); Sungkeun Myung, Suwon-si (KR); SUNGJOO AN, Suwon-si (KR); Taehee Yoo, Suwon-si (KR)

(73) Assignee: SAMSUNG ELECTRONICS CO., LTD., Suwon-si (KR)

(21) Appl. No.: 18/919,037

(22) Filed: Oct. 17, 2024

(30) Foreign Application Priority Data
Feb. 14, 2024 (KR) 10-2024-0021058

(51) Int. Cl. H01L 21/768; H01L 21/3213; H01L 21/67

(52) U.S. Cl. CPC H01L 21/7682; H01L 21/32136; H01L 21/32139; H01L 21/67253; H01L 21/76885

(57) ABSTRACT

There is provided a method of manufacturing a semiconductor device. The method includes forming a plurality of wires on an insulating layer, forming a sacrificial layer between the plurality of wires, forming a cover layer on the plurality of wires and the sacrificial layer, and removing the sacrificial layer formed below the cover layer by using mild plasma having a plasma damage rate to the insulating layer of 0.01 to 0.1 Å/s.

### CROSS-REFERENCE TO RELATED APPLICATION

This application is based on and claims priority to and the benefit of Korean Patent Application No. 10-2024-0021058 filed in the Korean Intellectual Property Office on Feb. 14, 2024, the entire contents of which are incorporated herein by reference.

### BACKGROUND

### 1. Field

The disclosure relates to a method of manufacturing a semiconductor device, and more particularly, to a method of manufacturing a semiconductor device using plasma treatment.

### 2. Description of the Related Art

Semiconductor devices may be manufactured by a variety of semiconductor manufacturing processes including etching, deposition, ashing, or cleaning processes.

In a front-end-of-line (FEOL) process, which is an initial stage process, for manufacturing a semiconductor device, an air gap structure to improve the signal transmission delay (RC Delay) in the wire. Similar to the FEOL process, a back-end-of-line (BEOL) process, which is a latter process in the manufacturing process of the semiconductor device, is also introducing an air gap structure to improve the signal transmission delay (RC Delay) in the wire.

In order to form the air gap structure, a sacrificial layer may be removed by pyrolysis. However, when pyrolysis is used to remove the sacrificial layer, a high-temperature heat treatment process is required for a long time. For example, a low-temperature heat treatment process at 400° C. or lower results in a low rate of sacrificial layer removal.

In addition, when pyrolysis is used to remove the sacrificial layer, real-time process monitoring is not possible, and it is difficult to control the residue substance after the heat treatment process. This can lead to problems, such as leakage current, caused by the residue substance. Moreover, providing additional measures to manage or address these problems may lead to longer process times, which may reduce productivity.

### SUMMARY

One or more aspects of the disclosure provide a method of manufacturing a semiconductor device that is capable of improving productivity by removing a sacrificial layer in a low temperature process using a plasma treatment apparatus.

According to an aspect of the disclosure, there is provided a method of manufacturing a semiconductor device, the method including: forming a plurality of wires on an insulating layer, the insulating layer provided on a substrate; forming a sacrificial layer between the plurality of wires; forming a cover layer on the plurality of wires and the sacrificial layer; and forming an air gap by removing the sacrificial layer using mild plasma having a plasma damage rate to the insulating layer of 0.01 to 0.1 Å/s.

According to another aspect of the disclosure, there is provided a method of manufacturing a semiconductor device, the method including: forming a mask on an insulating layer, the insulating layer provided on a substrate; patterning the insulating layer by using the mask to form an insulating layer pattern; forming a sacrificial material layer on the insulating layer and the mask; reducing a thickness of the sacrificial material layer to form a sacrificial layer and expose the mask; removing the mask; and removing the sacrificial layer by using mild plasma having a plasma damage rate to the insulating layer of 0.01 to 0.1 Å/s.

According to another aspect of the disclosure, there is provided a method of manufacturing a semiconductor device, the method including: forming a conductive layer and a mask on an insulating layer, the insulating layer provided on a substrate; etching the conductive layer to form a plurality of wires by using the mask; forming a sacrificial material layer on a space between the plurality of wires and the mask; reducing a thickness of the sacrificial material layer by an etch back process to form a sacrificial layer; forming a cover layer on the mask, the plurality of wires and the sacrificial layer; and forming of an air gap by removing the sacrificial layer by using mild plasma having a plasma damage rate to the insulating layer of 0.01 to 0.1 Å/s.

According to the embodiments, the sacrificial layer may be completely removed in a low-temperature process of 100° C. or lower by using the plasma treatment apparatus, thereby eliminating the risk due to residue substances and improving productivity by reducing process time.

Furthermore, by removing the sacrificial layer by using mild plasma with a plasma damage rate of 0.01 to 0.1 Å/s to the insulating layer, plasma induced damage (PID) to the insulating layer may be minimized.

In addition, the removal process of the sacrificial layer may be monitored in real time by using an optical emission spectroscopy device installed in the plasma treatment apparatus, allowing for more precise control of the air gap formation process.

Furthermore, while only temperature and pressure may be controlled in the heat treatment process, additional control parameters, such as the power of the plasma source, the flow rate, type, and mixing ratio of the reaction gases, in addition to temperature and pressure, may be obtained in the plasma treatment process, allowing for more precise control of the formation process of the air gap.

### BRIEF DESCRIPTION OF DRAWINGS

Embodiments herein are illustrated in the accompanying drawings, throughout which like reference letters indicate corresponding parts in the various figures. The embodiments herein will be better understood from the following description with reference to the following illustrative drawings. Embodiments herein are illustrated by way of examples in the accompanying drawings, and in which:

FIG. 1 is a flowchart schematically illustrating a method of manufacturing a semiconductor device according to an embodiment.

FIGS. 2 to 6 are diagrams illustrating the method of manufacturing the semiconductor device according to the embodiment.

FIG. 7 is a schematic diagram of a plasma treatment apparatus used in the method of manufacturing the semiconductor device according to the embodiment.

FIG. 8 is a graph illustrating a change in a radical signal measured by a optical emission spectroscopy device of the plasma treatment apparatus over time.

FIG. 9 is a graph illustrating a thickness and the amount of etch of a sacrificial layer removed by a plasma treatment apparatus and the amount of etch over time.

FIG. 10 is a schematic diagram of the plasma treatment apparatus used in the method of manufacturing the semiconductor device according to another embodiment.

FIG. 11 is a flowchart schematically illustrating a method of manufacturing a semiconductor device according to another embodiment.

FIGS. 12 to 17 are diagrams illustrating the method of manufacturing the semiconductor device according to another embodiment.

### DETAILED DESCRIPTION

Hereinafter, embodiments of the disclosure will be described with reference to accompanying drawings so as to be easily understood by a person ordinary skilled in the art. The disclosure may be variously implemented and is not limited to the following embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it may be directly on the other element or intervening elements may also be present. On the other hand, when an element is referred to as being “directly on” another element, there are no intervening elements present.

In addition, unless explicitly described to the contrary, the word “comprise”, and variations such as “comprises” or “comprising”, will be understood to imply the inclusion of stated elements but not the exclusion of any other elements.

Further, throughout the specification, when it is referred to as “in a plan view”, it means when a target part is viewed from above, and when it is referred to as “in a cross-sectional view”, it means when the cross-section obtained by cutting a target part vertically is viewed from the side.

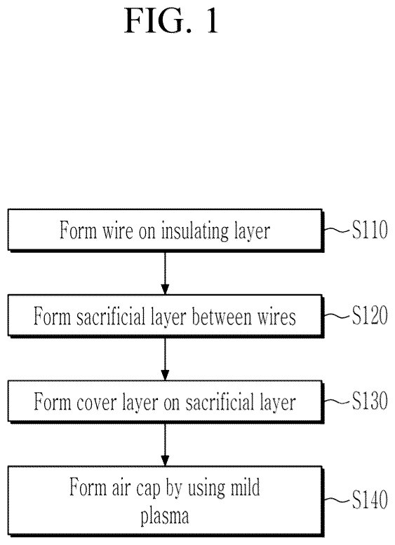

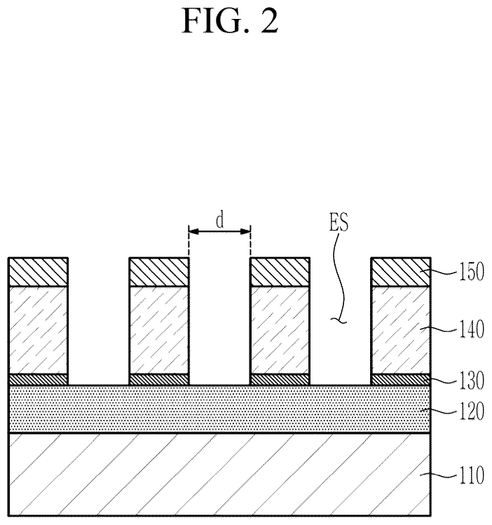

FIG. 1 is a flowchart schematically illustrating a method of manufacturing a semiconductor device according to an embodiment, and FIGS. 2 to 6 are diagrams illustrating the method of manufacturing the semiconductor device according to an embodiment.

According to an embodiment illustrated in FIG. 1, the method may include forming a plurality of wires on an insulating layer (S110), forming a sacrificial layer between the plurality of wires (S120), forming cover layer on the sacrificial layer (S130) and forming an air cap using mild plasma (S140). However, the disclosure is not limited thereto, and as such, according to another embodiment, one or more other operations may be performed in addition to the operations illustrated in FIG. 1. Referring to FIGS. 1 and 2, in operation (S110), the method of manufacturing a semiconductor device according to an embodiment of the disclosure includes forming an insulating layer 120 on a substrate 110, and forming a plurality of wires 140 on the insulating layer 120.

For example, the insulating layer 120 may be formed on the substrate 110. The substrate 110 may include, but is not limited to, a semiconductor chip formed by a front end of line (FEOL) process, and the like.

The insulating layer 120 may include a dielectric material having a dielectric constant smaller than a reference value. For example, the insulating layer 120 may include a dielectric material having a dielectric constant smaller than silicon oxide (SiO₂).

According to an embodiment, the dielectric material may include hydrocarbon compounds, carbides, carbon, or combinations thereof. For example, the dielectric material may be char or ash including a variety of hydrocarbon compounds, carbides, carbons, or combinations thereof, produced by pyrolysing hydrocarbon-based polymers, where the carbon rings of the hydrocarbon-based polymer are broken by pyrolysis. For example, the hydrocarbon-based polymer may include an aromatic hydrocarbon polymer, a (meth)acrylic polymer, a vinylpyridine polymer, a vinylester polymer, a vinylpyrrolidone polymer, an olefin polymer, or a combination thereof.

The dielectric material may include 60 wt % to 90 wt % carbon and 10 wt % to 40 wt % hydrogen. For example, the weight ratios of carbon and hydrogen may be based on the total weight of the dielectric material. For example, the dielectric material may include 70 wt % to 90 wt % carbon and 10 wt % to 30 wt % hydrogen, 72 wt % to 88 wt % carbon and 12 wt % to 28 wt % hydrogen, or 75 wt % to 85 wt % carbon and 15 wt % to 25 wt % hydrogen.

Moreover, the dielectric material may further include additional components including, but not limited to, halogen elements, nitrogen (N), oxygen (O), fluorine (F), sulfur (S), phosphorus (P), sodium (Na), magnesium (Mg), manganese (Mn), silicon (Si), sulfur (S), iron (Fe), or combinations thereof. The additional components may be derived from the components of the hydrocarbon-based polymer used to form the dielectric material. The additional components may be included at 0 wt % to 10 wt % based on the total weight of the dielectric material.

According to an embodiment, the dielectric material may include a carbon-doped silicon oxide (SiOC), or a porous silicon oxide.

For example, the carbon-doped silicon oxide is a silicon oxide in which at least some of the oxygen atoms bonded to the silicon are substituted with an organic group containing carbon. For example, the carbon-doped silicon oxide may be trimethylsilane (TMS) (BLACKDIAMOND™), tetramethylcyclotetrasilane (TMCTS) (Coral™), dimethyldimethoxysilane (DMDMOS) (Aurora™), or hydrogen silsesquioxane (HSG).

For example, the porous silicon oxide may be formed by oxidizing a carbon-doped silicon oxide and removing organic matters containing carbon. For example, when oxidizing agent is applied to a carbon-doped silicon oxide, silicon oxide (SiOx) may be formed by oxidizing the carbon-doped silicon oxide and an organic matter containing carbon may be removed.

Referring to FIG. 2, an anti-diffusion layer, a conductive layer, and a hard mask 150 may be sequentially stacked on the insulating layer 120, and the conductive layer and the anti-diffusion layer may be etched by using the hard mask 150 as an etch-resistant layer to form an anti-diffusion wire 130 and the plurality of wires 140.

The anti-diffusion wire 130 may prevent conductive components contained in the plurality of wires 140 from diffusing into the insulating layer 120 containing the dielectric material. The anti-diffusion wire 130 may also serve as an adhesive layer to attach the plurality of wires 140 to the insulating layer 120.

The plurality of wires 140 may be spaced apart from each other. For example, the plurality of wires 140 may be spaced apart from each other by a an interval d. For example, the interval d may be predetermined. The plurality of wires 140 spaced apart from each other may form an exposed space ES between adjacent wires 140. For example, the exposed space ED may expose the insulating layer 120.

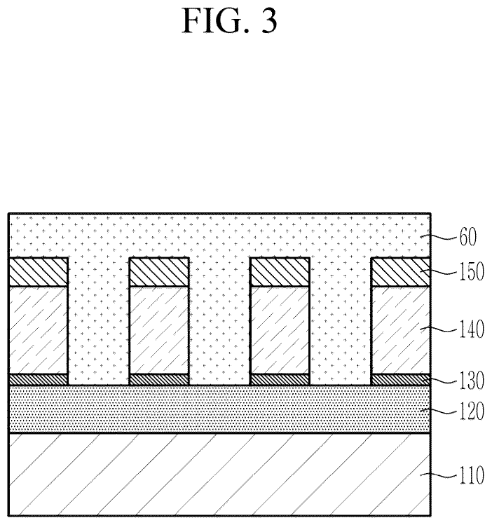

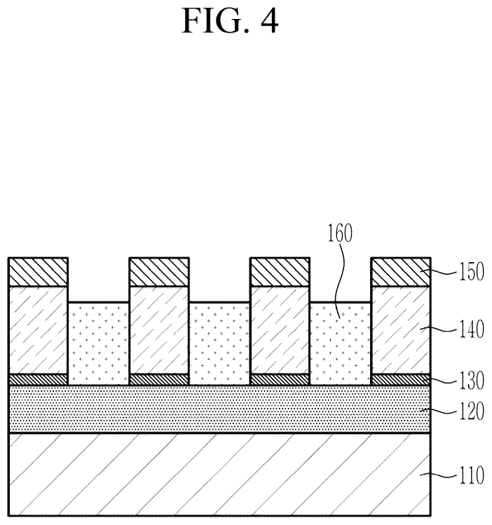

Referring to FIGS. 1 and 3, in operation (S120), a sacrificial material layer 60 may be deposited over the exposed space ES between the plurality of wires 140 and the hard mask 150. Thereafter, as illustrated in FIG. 4, an etch back process may be performed on the sacrificial layer 60. For example, the etch back process may be performed, using hydrogen plasma (H₂ plasma) or the like. The etch back process may be performed on the sacrificial layer 60 to the thickness of the sacrificial material layer 60 to form a recessed sacrificial layer 160 between the wires 140. However, the disclosure is not limited thereto, and as such, according to another embodiment, the sacrificial layer 240 may be etched in a different manner.

The sacrificial layer 160 may include a carbon composite formed by a thermopolymerization reaction of a precursor with a ring structure or a linear structure. For example, the sacrificial layer 160 may include a polyurea formed by a thermopolymerization reaction of isocyanate and amine.

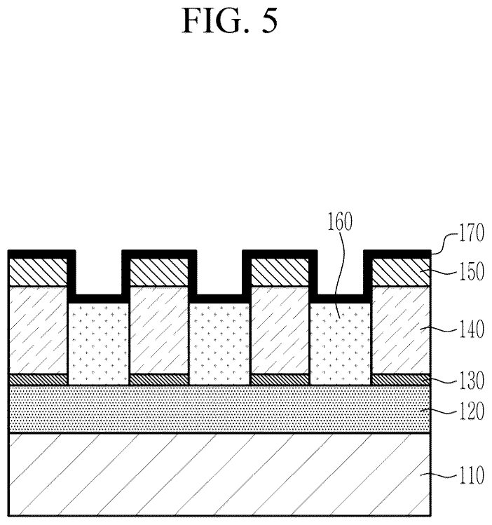

Referring to FIGS. 1 and 5, in operation (S130), a cover layer 170 may be formed over the hard mask 150 and the sacrificial layer 160.

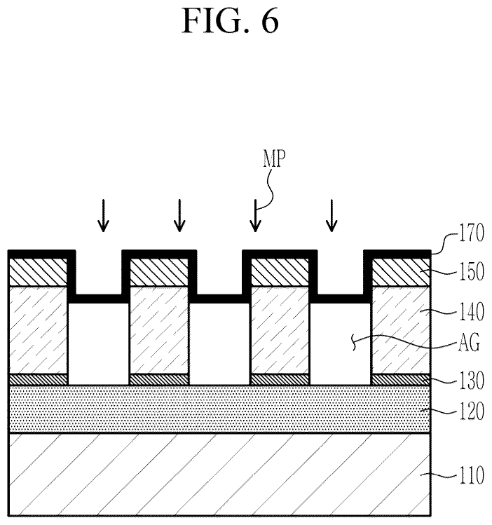

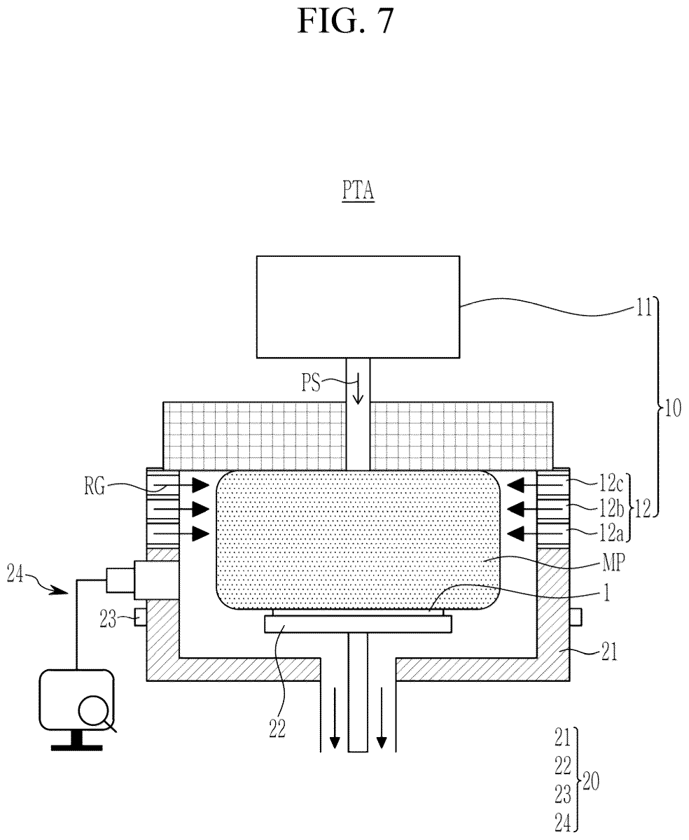

Referring to FIGS. FIGS. 1 and 6, in operation (S140), the sacrificial layer 160 formed under the cover layer 170 may be removed using a plasma treatment apparatus to form an air gap (AG). A plasma treatment apparatus is illustrated according to an embodiment in FIG. 7.

According to an embodiment, the sacrificial layer 160 may be removed by using mild plasma MP generated by the plasma treatment apparatus PTA. The mild plasma MP may refer to plasma having a plasma damage rate of 0.01 to 0.1 Å/s to the insulating layer 120 including a dielectric material.

Accordingly, damage to the insulating layer 120 by the mild plasma MP used to remove the sacrificial layer 160 may be minimized.

Furthermore, in the process of forming an air gap AG, the total thickness variation of the insulating layer 120 may be 10 Å or less. Thus, damage to the insulating layer 120 caused by the mild plasma MP may be minimized.

The plasma damage rate to the insulating layer 120 may be measured using the change in thickness of the insulating layer 120 caused by the mild plasma MP. In other words, the plasma damage rate to the insulating layer 120 may be measured by measuring the initial thickness of an insulating layer sample made of the same material as the insulating layer 120, exposing the insulating layer sample to mild plasma MP, and then wet etching the insulating layer sample by using an etchant, such as using hydrofluoric acid (HF), to measure the final thickness of the insulating layer sample.

Hereinafter, the plasma treatment apparatus PTA for forming the air gap AG will be described in detail with reference to the drawings.

FIG. 7 is a schematic diagram of the plasma treatment apparatus used in the method of manufacturing the semiconductor device according to the embodiment of the disclosure.

As illustrated in FIG. 7, the plasma treatment apparatus PTA used in the method of manufacturing the semiconductor device according to the embodiment of the disclosure may include a plasma generator 10 and a plasma chamber 20. However, the disclosure is not limited thereto, and as such, according to an embodiment, the plasma treatment apparatus PTA may include a controller configured to control one or more operations of the plasma treatment apparatus PTA. For example, the controller may include a memory storing one or more instructions, and a processor configured to executed the one or more instructions to perform the one or more operations of the plasma treatment apparatus PTA.

The plasma generator 10 may generate mild plasma MP. The plasma generator 10 may include a plasma source supply unit 11 and a reaction gas supply unit 12.

The plasma source supply unit 11 may supply a plasma source PS into the plasma chamber 20. The plasma source PS may include, but is not limited to, surface wave plasma (SWP), remote Inductively coupled plasma (ICP), and very high frequency plasma (VHF). The ICP utilizes an induced magnetic field induced by a coiled RF antenna to generate plasma.

The reaction gas supply unit 12 may supply reaction gas RG to the interior of the plasma chamber 20. The reaction gas RG may be excited by the plasma source PS to generate mild plasma MP.

The reaction gas supply 12 may include a plurality of sub-gas supply units 12a, 12b, and 12c that are installed on the side of the plasma chamber 20. For example, the plurality of sub-gas supply units 12a, 12b, and 12c may be installed to surround the plasma chamber 20. For example, the plurality of sub-gas supply units 12a, 12b, and 12c may have a ring shape.

The plurality of sub-gas supply units 12a, 12b, and 12c may include a first gas supply unit 12a, a second gas supply unit 12b, and a third gas supply unit 12c. For example, the first gas supply unit 12a is a lower gas supply unit, the second gas supply unit 12b is an intermediate gas supply unit, and the third gas supply unit 12c is an upper gas supply unit, installed in turn from the bottom according to the height of the side of the plasma chamber 20. The lower gas supply unit 12a may be located closest to a semiconductor device 1 including the sacrificial layer 160. However, the disclosure is not limited thereto, and as such, order and the arrangement of the sub-gas supply units 12a, 12b and 12c may be different.

According to an embedment, the mild plasma MP may be generated by a plasma source PS exciting reaction gas RG supplied through the lower gas supply unit 12a. For example, the mild plasma MP may be a plasma with the plasma damage rate of 0.01 to 0.1 Å/s to the insulating layer 120 generated by the plasma source PS exciting reaction gas RG supplied through the lower gas supply unit 12c. According to an embodiment, plasma with the plasma damage rate equal to or greater than 0.1 Å/s to the insulating layer 120 including the dielectric material may be generated by the plasma source PS exciting reaction gas RG supplied through the intermediate gas supply unit 12b and the upper gas supply unit 12c.

The reaction gas RG may include, but is not limited to, hydrogen (H₂), oxygen (O₂), carbon dioxide (CO₂), ammonia (NH₃), nitrogen (N₂), helium (He), argon (Ar), or mixed gas thereof.

In the plasma chamber 20, the semiconductor device 1 having the sacrificial layer 160 is located, and the sacrificial layer 160 of the semiconductor device 1 may be removed by using the mild plasma MP to form an air gap AG.

The plasma chamber 20 may include a chamber main body 21, a plasma electrode 22, a temperature control unit 23, and an optical emission spectroscopy device (OES) device 24. The temperature control unit 23 may be a controller or a control circuit.

The chamber main body 21 may including a stage (or a platform) for receiving the semiconductor device 1. Moreover, the chamber main body 21 may include a space in which the mild plasma MP is generated. For example, the space in which the mild plasma MP is generated may be provided above the stage receiving the semiconductor device 1.

The plasma electrode 22 applies a voltage to the plasma source PS and the reaction gas RG to generate the mild plasma MP, and may act as a support unit on which the semiconductor device 1 is seated.

The temperature control unit 23 may include a heater or the like surrounding the chamber main body 21. The sacrificial layer 160 may be removed at a low temperature of 100 degrees or less by using the temperature control unit 23.

The optical emission spectroscopy device 24 may include an optical sensor to detect luminescence spectra, a luminescence spectroscopy unit to analyze the luminescence spectra, and the like. The optical emission spectroscopy device 24 may determine the point at which the intensity of the radical signal becomes constant as an end point EP of the plasma treatment process and turn off the plasma treatment apparatus.

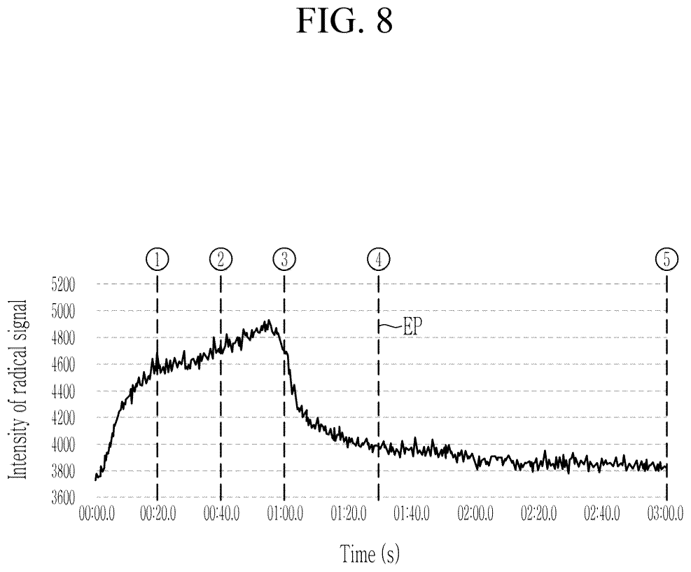

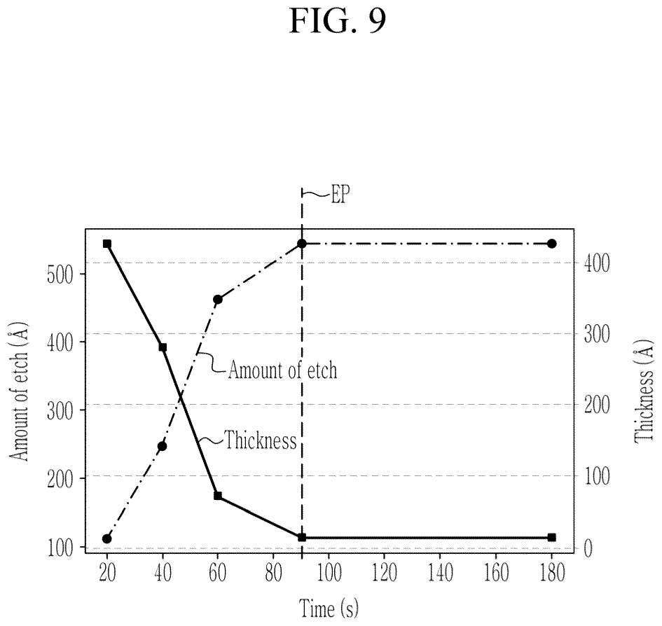

FIG. 8 is a graph illustrating a change in a radical signal measured by the optical emission spectroscopy device of the plasma treatment apparatus over time, and FIG. 9 is a graph illustrating a thickness of a sacrificial layer removed by a plasma treatment apparatus and the amount of etch over time.

As illustrated in FIG. 8, a point at which the intensity of the time-varying radical signal becomes constant may be determined as the end point EP of the plasma treatment process. Moreover, as illustrated in FIG. 9, a point at which the thickness and the amount of etching of the sacrificial layer 160 removed by the plasma treatment apparatus becomes constant may also be determined as the end point EP of the plasma treatment process. Thus, the end point EP of the plasma treatment process may be accurately determined in real time and the plasma treatment apparatus may be turned off.

In this way, in the process of forming the air gap AG, the change in the radical signal of the mild plasma MP may be measured by using the optical emission spectroscopy device 24 of the plasma treatment apparatus. This allows the formation process of the air gap AG to be monitored in real time to accurately determine a time point of turning off the plasma treatment process. Thus, the formation process of the air gap AG may be controlled more precisely.

While the reaction gas supply unit of the embodiment includes the plurality of sub-gas supply units 12a, 12b, and 12c, the disclosure is not limited thereto, and as such, according to another embodiment, the reaction gas may be supplied in another manner. For example, a reaction gas supply unit may supply the reaction gas through a shower head.

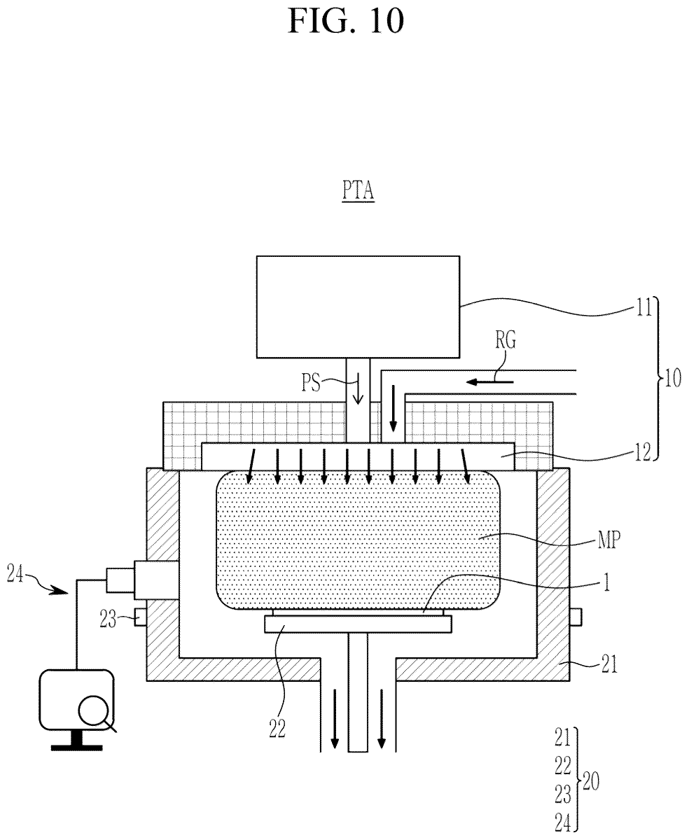

FIG. 10 is a schematic diagram of the plasma treatment apparatus used in the method of manufacturing the semiconductor device according to another embodiment.

As illustrated in FIG. 10, the reaction gas supply unit 12 may include a shower head 12 that disperses and supplies reaction gas RG to the interior of the plasma chamber 20.

The mild plasma MP may be generated by a plasma source PS exciting reaction gas RG supplied through the shower head 12.

According to an embodiment, the sacrificial layer 160 may be completely removed in a low-temperature process of 100° C. or lower by using the plasma treatment apparatus PTA, thereby eliminating the risk due to residue substances and improving productivity by reducing process time.

In the process of forming the air gap AG, the process temperature may be controlled to 100° C. or lower using the temperature control unit of the plasma treatment apparatus. In other words, when pyrolysis is used to remove the sacrificial layer, the heat treatment process at a high temperature of 400° C. or higher needs to be carried out for a long time, and residue substances are easy to be generated, which may cause leakage current due to the residue substances.

However, in the plasma treatment apparatus using the mild plasma MP, as in the present embodiment, the sacrificial layer may be completely removed in a short time even with a low-temperature process of 100° C. or lower, thereby minimizing the generation of leakage current, which may improve productivity.

In addition, while only temperature and pressure may be controlled in the heat treatment process, additional control parameters, such as the power of the plasma source, the flow rate, type, and mixing ratio of the reaction gases, in addition to temperature and pressure, may be obtained in the plasma treatment process, allowing for more precise control of the formation process of the air gap AG.

In the above embodiment, the air gap is formed by removing the sacrificial layer with minimal damage to the insulating layer including the dielectric material using mild plasma, but other embodiments are possible in which an insulating layer pattern is completed by removing the sacrificial layer with minimal damage to the insulating layer including the dielectric material using mild plasma.

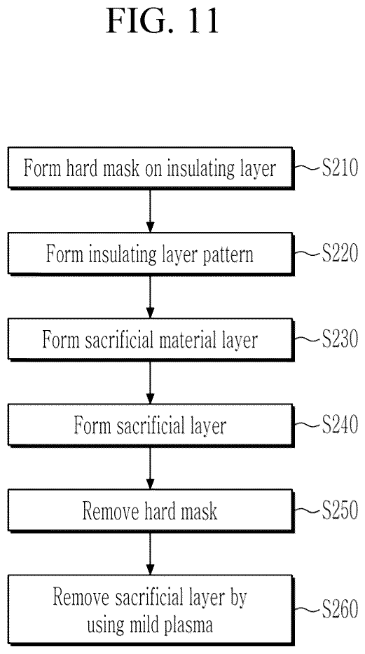

Hereinafter, a method of manufacturing a semiconductor device according to another embodiment of the disclosure will be described in detail with reference to FIGS. 11 to 16.

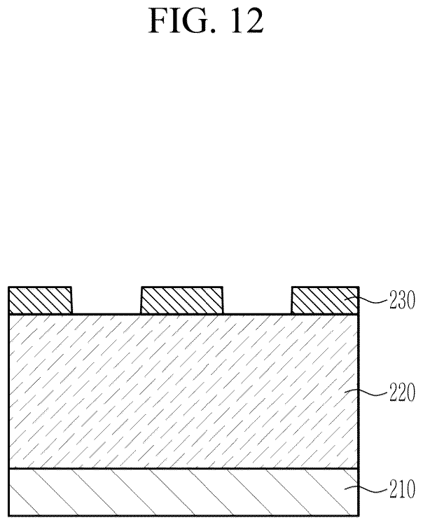

FIG. 11 is a flowchart schematically illustrating a method of manufacturing a semiconductor device according to another embodiment, and FIGS. 12 to 17 are diagrams illustrating the method of manufacturing the semiconductor device according to another embodiment.

According to an embodiment illustrated in FIG. 11, the method may include forming a hard mask on an insulating layer (S210), forming an insulating layer pattern (S220), forming a sacrificial material layer on the insulating layer pattern (S230), forming the sacrificial layer (S240), removing the hard mask (S250), and removing the sacrificial layer by using mild plasma (S260). Referring to FIGS. 11 and 12, in operation (S210), the method of manufacturing a semiconductor device according to another embodiment of the disclosure may include forming a hard mask 230 on an insulating layer 220 on a substrate 210. The substrate 210 may include a semiconductor chip formed by a front end of line (FEOL) process, and the like. The insulating layer 220 may include a dielectric material having a smaller dielectric constant than a reference value. For example, the insulating layer 120 may include a dielectric material having a smaller dielectric constant than silicon oxide (SiO₂).

The hard mask 230 may have a pattern that exposes one or more portions of the insulating layer 220. For example, as shown in FIG. 12, the hard mask 230 may have open space in between to expose an upper surface of the insulation layer 220.

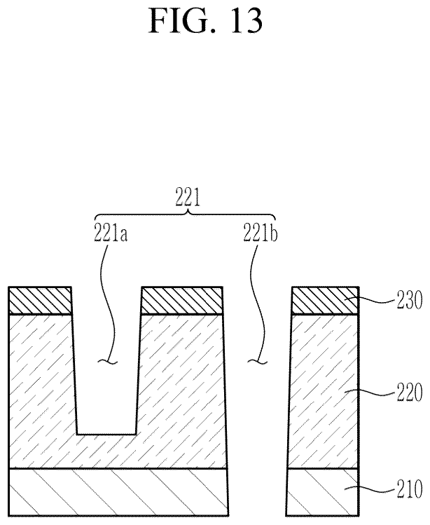

Referring to FIGS. 11 and 13, in operation (S220), the insulating layer 220 may be patterned by using the hard mask 230 as an etch mask, to form an insulating layer pattern 221 on the insulating layer 220. The insulating pattern 221 may include a trench 221a or a through-hole 221b formed in the insulating layer 220. However, the disclosure is not limited to the patterns illustrated in FIG. 13, and as such, various other patterns may be formed on the insulating layer 220.

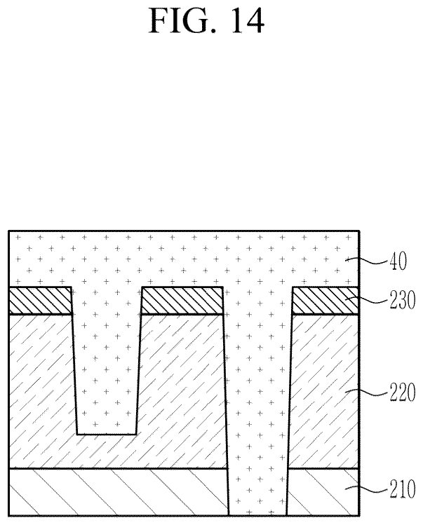

Referring to FIGS. 11 and 14, in operation (S230), a sacrificial material layer 40 may be formed S230 on the insulating layer 220 and the hard mask 230. The sacrificial material layer 40 may be formed on the insulating layer 220. For example, the sacrificial material layer 40 may be formed to cover the insulating layer 220 to prevent etching of the insulating layer 220 when the hard mask 230 is etched in a later process. The sacrificial material layer 40 may fill the insulating layer pattern 221 formed on the insulating layer 220. For example, sacrificial material layer 40 may fill the trench 221a or the through-hole 221b. The sacrificial material layer 40 may include a carbon composite formed by a thermopolymerization reaction of a precursor with a ring structure or a linear structure.

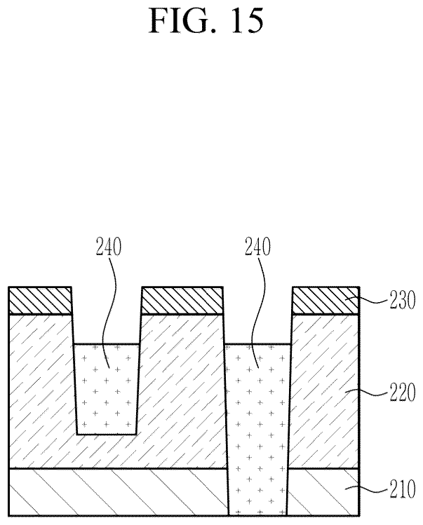

Referring to FIGS. 11 and 15, in operation (S240), the thickness of the sacrificial material layer 40 may be reduced by an etch back process, such as ashing, to form a sacrificial layer 240. However, the disclosure is not limited thereto, and as such, according to another embodiment, the sacrificial layer 240 may be etched in a different manner. In this case, the hard mask 230 covered by the sacrificial material layer 40 is exposed to the outside, but the insulating layer 220 covered by the sacrificial layer 240 is only partially exposed to the outside, and most of the insulating layer 220 is not exposed.

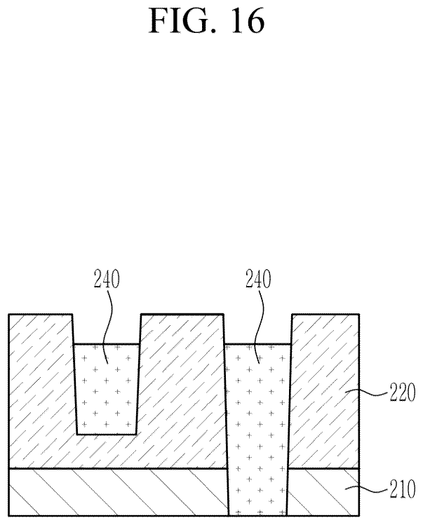

Referring to FIGS. 11 and 16, in operation (S250), an etching process may be performed to remove the hard mask 230. In this case, the insulating layer 220 is largely covered by the sacrificial layer 240, so the insulating layer 220 is not etched in the etching process that removes the hard mask 230.

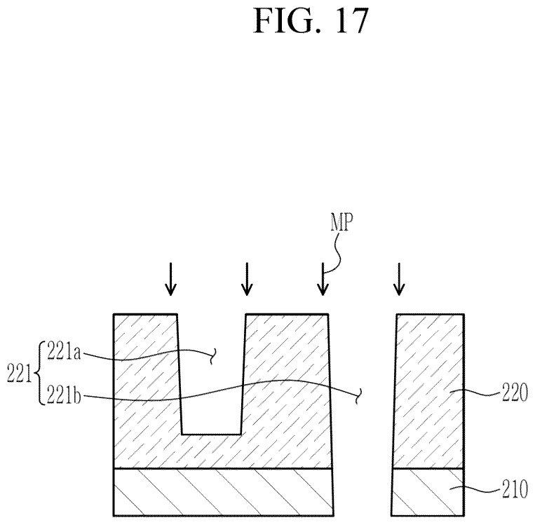

Referring to FIGS. 11 and 17, in operation (S260), the sacrificial layer 240 filled in the insulating layer pattern 221 of the insulating layer 220 is removed by using a plasma treatment apparatus PTA to complete the insulating layer pattern 221.

Here, the mild plasma MP generated by the plasma treatment apparatus PTA may be utilized to remove the sacrificial layer 240. The mild plasma MP may refer to plasma having a plasma damage rate of 0.01 to 0.1 Å/s to the insulating layer 220 including a dielectric material.

Thus, damage to the insulating layer 220 by the mild plasma MP used to remove the sacrificial layer 240 may be minimized.

Further, in the process of removing the sacrificial layer 240 that fills the insulating layer pattern 221 of the insulating layer 220, the change in the radical signal of the mild plasma MP may be measured by using the luminescence spectroscopy apparatus 24 of the plasma processing device. Accordingly, the removal process of the sacrificial layer 240 may be monitored in real time to accurately determine a time point of turning off the plasma treatment process. Thus, the removal process of the sacrificial layer 240 may be more precisely controlled.

Although embodiments of the disclosure has been described in detail, the scope of the disclosure is not limited by the embodiments. Various changes and modifications using the basic concept of the disclosure defined in the accompanying claims by those skilled in the art shall be construed to belong to the scope of the present disclosure.

What is claimed is:

1. A method of manufacturing a semiconductor device, the method comprising:
forming a plurality of wires on an insulating layer, the insulating layer provided on a substrate;
forming a sacrificial layer between the plurality of wires;
forming a cover layer on the plurality of wires and the sacrificial layer; and
forming an air gap by removing the sacrificial layer using mild plasma having a plasma damage rate to the insulating layer of 0.01 to 0.1 Å/s.

2. The method of claim 1, wherein the plasma damage rate to the insulating layer is measured by using a change in thickness of a sample insulating layer caused by the mild plasma.

3. The method of claim 1, wherein in the forming of the air gap, a total change in thickness of the insulating layer is 10 Å or less.

4. The method of claim 1, wherein the forming of the air gap comprises controlling a process temperature to be less than or equal to 100 degrees.

5. The method of claim 1, wherein the forming of the air gap comprises monitoring the forming of the air gap in real time through a change in a radical signal of the mild plasma by using a luminescence spectroscope device.

6. The method of claim 1, wherein the insulating layer comprises a dielectric material having a smaller dielectric constant than silicon oxide (SiO₂).

7. The method of claim 1, wherein the sacrificial layer comprises a carbon composite formed by a thermopolymerization reaction of a precursor with a ring structure or a linear structure.

8. The method of claim 1, wherein the mild plasma is produced by a plasma generating unit of a plasma treatment apparatus, and
wherein the sacrificial layer is removed in a plasma chamber of the plasma treatment apparatus using the mild plasma.

9. The method of claim 8, further comprising:
supplying, by a plasma source supply unit, a plasma source into a plasma chamber; and
supplying, a reaction gas supply unit, reaction gas into the plasma chamber to react with the plasma source to produce the mild plasma.

10. The method of claim 9, wherein the reaction gas supply unit comprises a plurality of sub-gas supply units installed on a side of the plasma chamber, and
wherein the plurality of sub-gas supply units includes a first gas supply unit, a second gas supply unit, and a third gas supply unit installed on the plasma chamber, the first gas supply unit being provided at a level lower than the second gas supply unit and the third gas supply unit in the plasma chamber, and
wherein the mild plasma is generated by the plasma source exciting the reaction gas supplied through the first gas supply unit.

11. The method of claim 9, wherein the reaction gas supply unit comprises a shower head for dispersing and supplying the reaction gas into the plasma chamber, and
wherein the mild plasma is generated by the plasma source exciting the reaction gas supplied through the shower head.

12. The method of claim 9, wherein the plasma source comprises one of surface wave plasma (SWP), remotely inductively coupled plasma (ICP), and very high frequency plasma (VHF).

13. A method of manufacturing a semiconductor device, the method comprising:
forming a mask on an insulating layer, the insulating layer provided on a substrate;
patterning the insulating layer by using the mask to form an insulating layer pattern;
forming a sacrificial material layer on the insulating layer and the mask;
reducing a thickness of the sacrificial material layer to form a sacrificial layer and expose the mask;
removing the mask; and
removing the sacrificial layer by using mild plasma having a plasma damage rate to the insulating layer of 0.01 to 0.1 Å/s.

14. The method of claim 13, wherein in the removing of the sacrificial layer, a total change in thickness of the insulating layer is 10 Å or less.

15. The method of claim 13, wherein the removing of the sacrificial layer comprises controlling controls a process temperature to be less than or equal to 100 degrees.

16. The method of claim 13, further comprising monitoring the removing process of the sacrificial layer in real time through a change in a radical signal of the mild plasma by using a luminescence spectroscope device.

17. The method of claim 13, wherein the insulating layer comprises a dielectric material having a smaller dielectric constant than silicon oxide (SiO₂).

18. The method of claim 13, wherein the sacrificial layer comprises a carbon composite formed by a thermopolymerization reaction of a precursor with a ring structure or a linear structure.

19. A method of manufacturing a semiconductor device, the method comprising:
forming a conductive layer and a mask on an insulating layer, the insulating layer provided on a substrate;
etching the conductive layer to form a plurality of wires by using the mask;
forming a sacrificial material layer on a space between the plurality of wires and the mask;
reducing a thickness of the sacrificial material layer by an etch back process to form a sacrificial layer;
forming a cover layer on the mask, the plurality of wires and the sacrificial layer; and
forming of an air gap by removing the sacrificial layer by using mild plasma having a plasma damage rate to the insulating layer of 0.01 to 0.1 Å/s.

20. The method of claim 19, wherein the insulating layer comprises a dielectric material having a smaller dielectric constant than silicon oxide (SiO₂).
